(19) United States
(12) Patent Application Publication
(10) Pub. No.: US 2025/0021713 A1
(43) Pub. Date: Jan. 16, 2025

(54) GENERATION DEVICE

(71) Applicant: TOYOTA JIDOSHA KABUSHIKI KAISHA, Toyota-shi (JP)

(72) Inventors: Yuko MIZUNO, Nagoya-shi (JP); Makoto MATSUSHITA, Ichinomiya-shi (JP); Hayato MIZUMA, Tokyo (JP); Kohei MIWA, Sunto-gun (JP); Naoki YAMADA, Kasugai-shi (JP)

(73) Assignee: TOYOTA JIDOSHA KABUSHIKI KAISHA, Toyota-shi (JP)

(21) Appl. No.: 18/675,588

(22) Filed: May 28, 2024

(30) Foreign Application Priority Data
Jul. 10, 2023 (JP) 2023-112873

(51) Int. Cl. G06F 30/15; G06T 17/05

(52) U.S. Cl. CPC G06F 30/15; G06T 17/05

(57) ABSTRACT

The server generates background data based on the captured data of the drive recorder provided by the user of the vehicle, and generates data including the background data as course data of the travel simulator executed by the user terminal, and distributes the data to the user.

### CROSS-REFERENCE TO RELATED APPLICATION

This application claims priority to Japanese Patent Application No. 2023-112873 filed on Jul. 10, 2023, incorporated herein by reference in its entirety.

### BACKGROUND

### 1. Technical Field

The present invention relates to a generation device that generates background data for a travel simulator of a vehicle.

### 2. Description of Related Art

As a travel simulator of a vehicle to be used for a game, driving training, etc., there is a simulator that simulates travel of a vehicle on a road in the real world. Further, Japanese Unexamined Patent Application Publication No. 2001-22264 (JP 2001-22264 A) describes a travel simulator that acquires traffic information and weather information in the real world and reflects such information in simulation.

### SUMMARY

In the travel simulator described above, the user can travel only on a course prepared in advance.

In order to address the above issue, a generation device generates three-dimensional computer graphics background data to be used in a travel simulator that simulates travel of a vehicle on a road in a real world, based on image data from a drive recorder.

Background data for a travel simulator corresponding to the real world can be easily generated.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram schematically showing a configuration of an embodiment of a generation device; and

FIG. 2 is a sequence diagram illustrating a processing procedure related to generation and distribution of course data in the generation device.

### DETAILED DESCRIPTION OF EMBODIMENTS

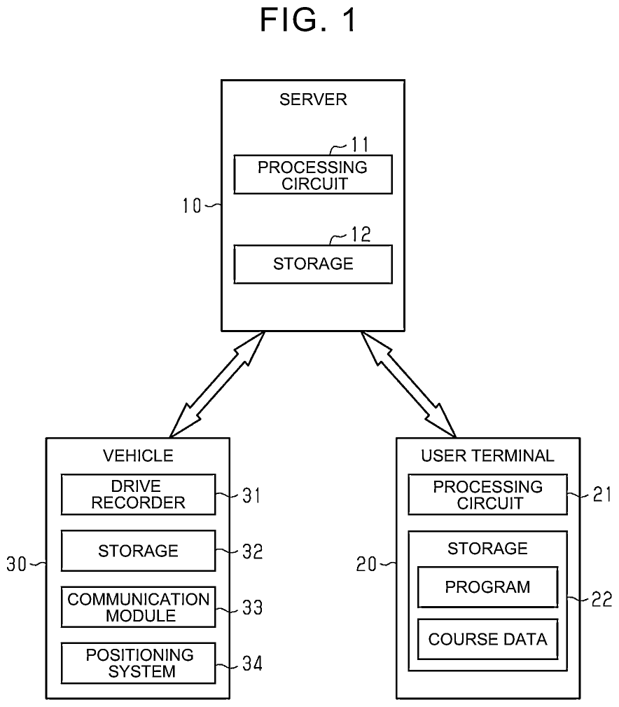

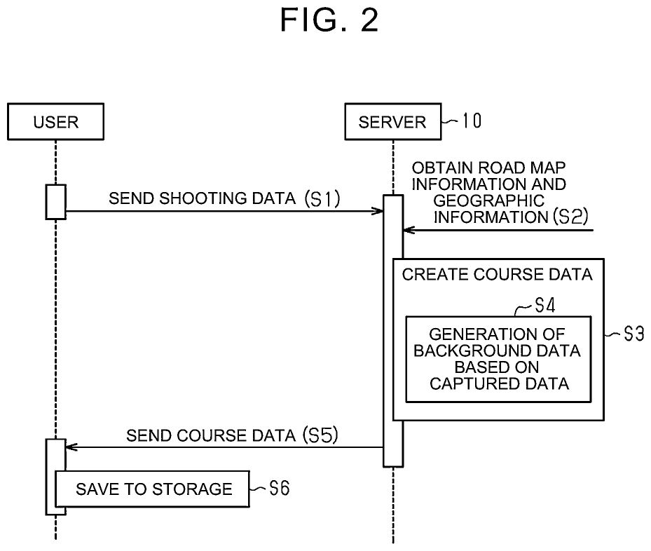

Hereinafter, an embodiment of a generation device will be described in detail with reference to FIGS. 1 and 2.

### Configuration of Generation Device

First, with reference to FIG. 1, a configuration of a generation device according to the present embodiment will be described. The generation device of the present embodiment is configured as an apparatus for generating background data used in a travel simulator. The travel simulator is configured to simulate the travel of the vehicle on a road in the real world. The travel simulator may be a simulator for a game such as a race, or may be a simulator for training driving a vehicle.

In the vehicle 30 shown in FIG. 1, a drive recorder 31 that captures an image of the outside of the vehicle is installed. Further, the vehicle 30 includes a storage 32 capable of storing captured data of the drive recorder 31, a communication module 33 for external communication, and a positioning system 34 for detecting the position of the vehicle 30. Examples of the positioning system 34 include a satellite positioning system. The shooting data of the drive recorder 31 recorded in the storage 32 includes the shooting position and the shooting date and time information acquired from the positioning system 34 in addition to the image of the outside of the vehicle captured by the drive recorder 31.

The travel simulator is executed on a computer terminal (hereinafter, referred to as user terminal 20) owned by a user of the vehicle 30. Examples of the user terminal 20 include a personal computer, a consumer game machine, and a smartphone. The user terminal 20 includes a processing circuit 21 and a storage 22. The storage 22 stores a program of the travel simulator. The user terminal 20 operates as a travel simulator by reading and executing the program by the processing circuit 21. The storage 22 stores data of a traveling course that can be traveled on the traveling simulator (hereinafter, referred to as course data). The travel simulator is configured to acquire new course data so that a course that can travel on the simulator can be added.

The generation device of the present embodiment includes the server 10 illustrated in FIG. 1. The server 10 includes a processing circuit 11 and a storage 12. The server 10 executes a program stored in the storage 12 by the processing circuit 11 to perform processing related to the generation of the course data of the travel simulator.

### Creation of Course Data

Next, a process of generating course data performed by the server 10 will be described with reference to FIG. 2. The server 10 creates course data using the captured data of the drive recorder 31 when the vehicle 30 actually travels on the course to be generated.

When creating the course data, the user of the vehicle 30 transmits the captured data of the drive recorder 31 to the server 10 (S1). In the case of FIG. 2, the photographing data is directly transmitted from the vehicle 30 to the server 10. The captured data may be transmitted to the server 10 via the user terminal 20. In this situation, the captured image of the drive recorder 31 is first transferred to the user terminal 20 using a removable storage medium such as a memory card or Wi-Fi communication. Then, the captured data is transmitted from the user terminal 20 to the server 10.

On the other hand, the server 10 acquires information required for creating course data other than the captured data, for example, road-map information around the course, and terrain information (S2). Then, the server 10 creates the course-data based on them (S3) and transmits the course-data to the user terminal 20 (S5). The user terminal 20 stores the received course data in the storage 22 (S6).

The course data includes the background data of the course in addition to the data of the course itself. At the time of creating the course data, the server 10 generates background data based on the captured data of the drive recorder 31 (S4). Background includes 3D modelling of objects such as buildings/vegetation around the course. The captured data of the drive recorder 31 includes an image of an object viewed from a plurality of angles. In addition, the imaging data includes information on the imaging positions of the plurality of images. The server 10 creates 3D modeling of the objects by photogrammetry using the plurality of images. Specifically, the server 10 analyzes and integrates parallax information of images of objects captured from a plurality of angles to create a 3D model of the object. In addition, the server 10 determines the colors and textures of 3D images by analyzing the images. 2D image may be a background image, instead of a 3D image, for a distant object with a small change in appearance as the vehicle 30 moves along the course.

### Action Effect of Embodiment

The operation and effects of the present embodiment will be described. The server 10 generates background data based on the captured data of the drive recorder 31 provided by the user of the vehicle 30. Then, the server 10 creates course data including the generated background data and transmits the course data to the user of the vehicle 30. As a result, the user can travel the course captured by the drive recorder 31 in the travel simulator.

According to the generation device of the present embodiment described above, the following effects can be obtained.
(1) The course actually traveled by the user can be easily added to the course that can be traveled by the travel simulator.
(2) When the course data of the travel simulator is created using only the existing road map information and topographical information, it is not possible to reproduce the appearance of objects around the course. On the other hand, the server 10 of the present embodiment generates background data of the course that can be traveled by the travel simulator based on the captured data of the drive recorder 31. That is, the server 10 generates background data based on the video captured from the actual vehicle 30. Therefore, the background of the course that can be traveled by the travel simulator can be brought close to reality.

### Other Embodiment

The present embodiment can be modified as follows. The present embodiment and the following modifications can be implemented in combination with each other as long as they are not technically contradictory.

The server 10 may be configured to individually generate the background data according to any one of a time zone at the time of photographing the photographing data, a season, and a weather at the time of photographing. The appearance of objects around the course varies depending on the time zone, the season, and the weather. Therefore, if the background data is individually generated by these, the change in the appearance of the object due to the time zone, the season, and the weather can be reproduced on the traveling simulator. For example, background data based on daytime photographing data and background data based on nighttime photographing data are separately generated. In this case, the course data created by the server 10 includes background data for daytime and nighttime. In such a case, in the travel simulator, the time zone to be traveled is designated, and the background data to be used is switched according to the designated time zone, whereby the background rendering suitable for the time zone becomes possible.

When the image of the signboard is included in the captured data, the server 10 may be configured to change the display content of the signboard at the time of generating the background data. In some cases, the signboard or the like of the shop may require the permission of the owner for use in the traveling simulator. In such a case, if the display content of the signboard in the background data is different from the actual content, the permission is not necessary. In addition, the display content of the signboard in the background data is designated by the traveling simulator or the provider of the course data, so that the advertisement can be performed.

The server 10 may be configured to set the vehicle included in the image of the captured data to another vehicle appearing in the travel simulator. In this case, the server 10 identifies the vehicle type, the body color, and the like of the vehicle by image analysis of the captured data, and transmits the information together with the course data to the user terminal 20. The user terminal 20 causes a vehicle provided with information from the server 10 to appear as another vehicle encountered during traveling in the traveling simulator. In such a case, the vehicle encountered while traveling in the real world appears in the traveling simulator, and therefore the experience in the traveling simulator becomes close to the real world.

The user terminal 20 may generate the background data and the course data. Further, the user terminal 20 different from the terminal that executes the travel simulator may generate background data and course data.

What is claimed is:

1. A generation device configured to generate background data to be used in a travel simulator that simulates travel of a vehicle on a road in a real world, based on captured data from a drive recorder.

2. The generation device according to claim 1, wherein:
the generation device is configured to generate the background data based on the captured data provided from a user of a vehicle in which the drive recorder is installed; and
the generation device is configured to transmit the generated background data to the user.

3. The generation device according to claim 1, wherein the generation device is configured to individually generate the background data according to any one of a time zone, a season, and a weather at a time of capturing of the captured data.

4. The generation device according to claim 1, wherein the generation device is configured to change a display content of a signboard when generating the background data when an image of the signboard is included in the captured data.

5. The generation device according to claim 1, wherein the generation device is configured to set a vehicle included in an image of the captured data to another vehicle that appears in the travel simulator.
